(19) United States
(12) Patent Application Publication
(10) Pub. No.: US 2019/0113133 A1
(43) Pub. Date: Apr. 18, 2019

(54) VEHICLE AND CONTROL METHOD FOR THE SAME

(71) Applicants: Hyundai Motor Company, Seoul (KR); Kia Motors Corporation, Seoul (KR)

(72) Inventors: Seunghyun Woo, Seoul (KR); Gi Beom Hong, Bucheon-si (KR); Daeyun An, Anyang-si (KR)

(73) Assignees: Hyundai Motor Company, Seoul (KR); Kia Motors Corporation, Seoul (KR)

(21) Appl. No.: 15/833,834

(22) Filed: Dec. 6, 2017

(30) Foreign Application Priority Data
Oct. 16, 2017 (KR) 10-2017-0133873

(51) Int. Cl. F16H 59/08; G01R 33/028

(52) U.S. Cl. CPC F16H 59/08; G01R 33/0283

(57) ABSTRACT

A vehicle configured to receive an input of a shift command corresponding to a change in position of a vehicle accessory seated in a shift command input portion and a control method for the same, may include a vehicle accessory; a shift command input portion in which the vehicle accessory is configured to be seated and which receives an input of a shift command corresponding to a change in position of the seated vehicle accessory; a shift device configured to change a shift range; and a controller configured to control the shift device to change the shift range in accordance with the shift command input by the shift command input portion.

### CROSS-REFERENCE TO RELATED APPLICATION

The present application claims priority to Korean Patent Application No. 10-2017-0133873, filed on Oct. 16, 2017 in the Korean Intellectual Property Office, the entire contents of which is incorporated herein for all purposes by this reference.

### BACKGROUND OF THE INVENTION

### Field of the Invention

The present invention relates to a vehicle including a shift command input portion configured to receive an input of a shift command and a control method for the same.

### Description of Related Art

Vehicles refer to transportation devices having fossil fuels, electricity, or the like as power sources and configured to travel on roads or tracks.

Speed of such a vehicle may be basically changed by operating a shift device configured to receive driving force from an engine and transmit the driving force to wheels and a shift command input portion capable of changing a shift range of the shift device. The shift range can form a unique shift path, and a driver can change the speed of the vehicle by operating the shift command input portion in accordance with the formed shift path.

Unlike a mechanical shift command input portion in the related art, a shift command input portion of a shift-by-wire (SBW) type which is recently actively being studied may be provided to receive an input of a shift command in accordance with a shift path formed in various ways.

The information disclosed in the present Background of the Invention section is only for enhancement of understanding of the general background of the invention and may not be taken as an acknowledgement or any form of suggestion that the present information forms the prior art already known to a person skilled in the art.

### BRIEF SUMMARY

Various aspects of the present invention are directed to providing a vehicle configured to receive an input of a shift command corresponding to a change in position of a vehicle accessory seated in a shift command input portion and a control method for the same.

Additional aspects of the disclosure will be set forth in part in the description which follows and, in part, will be obvious from the description, or may be learned by practice of the disclosure.

In accordance with one aspect of the present invention, a vehicle according to an exemplary embodiment of the present invention may include a vehicle accessory; a shift command input portion in which the vehicle accessory is configured to be seated and which receives an input of a shift command corresponding to a change in position of the seated vehicle accessory; a shift device configured to change a shift range; and a controller configured to control the shift device to change the shift range in accordance with the shift command input by the shift command input portion.

The shift command input portion may receive an input of a shift command corresponding to the change in position including at least one of forward movement, backward movement, rotation, upward movement, and downward movement of the seated vehicle accessory.

The shift command input portion may include a seating portion in which the vehicle accessory is seated; and a detector configured to detect a change in position of the vehicle accessory seated in the seating portion.

The vehicle accessory may include a metal portion provided therein.

The seating portion may include an electromagnet configured to provide attraction to the metal portion of the vehicle accessory.

The detector may form a magnetic field around the seating portion and detect a change in position of the vehicle accessory in accordance with a change in the formed magnetic field.

The detector may include a permanent magnet configured to form a magnetic field around the seating portion; and a coil through which an induced current corresponding to the change in the formed magnetic field flows.

The shift command input portion may receive an input of a startup command when the vehicle accessory is seated.

The shift command input portion may receive an input of a shutoff command when the seated vehicle accessory is separated.

The vehicle accessory may be provided in a form of a vehicle.

The vehicle accessory may receive an input of at least one of a door lock command and a door unlock command of the vehicle.

In accordance with another aspect of the present invention, a control method for a vehicle according to an exemplary embodiment of the present invention is a control method for a vehicle including a shift command input portion in which a vehicle accessory is configured to be seated, the control method including: receiving an input of a shift command corresponding to a change in position of the seated vehicle accessory; and changing a shift range in accordance with the input shift command.

The receiving of the input of the shift command may include receiving an input of a shift command corresponding to the change in position including at least one of forward movement, backward movement, rotation, upward movement, and downward movement of the seat vehicle accessory.

The receiving of the input of the shift command may include forming a magnetic field around a seating portion in which the vehicle accessory is seated; and receiving an input of the shift command according to a change in the magnetic field generated due to a change in position of the vehicle accessory.

The forming of the magnetic field may include forming the magnetic field using a permanent magnet provided near the seating portion.

The receiving of the input of the shift command in accordance with the change in the magnetic field may include receiving an input of the shift command on the basis of an induced current corresponding to the change in the magnetic field.

The control method for the vehicle may further include starting the vehicle when the vehicle accessory is seated in the shift command input portion.

The starting of the vehicle may include starting the vehicle when the vehicle accessory is seated in the shift command input portion due to attraction provided by an electromagnet of the shift command input portion.

The control method for the vehicle may further include shutting off the vehicle when the seated vehicle accessory is separated from the shift command input portion.

The receiving of the input of the shift command may include receiving an input of a shift command corresponding to a change in position of the seated vehicle accessory provided in a vehicle shape.

The control method for the vehicle may further include receiving an input of at least one of a door lock command and a door unlock command of the vehicle by the vehicle accessory.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a diagram showing an external form of a vehicle according to an exemplary embodiment of the present invention;

FIG. 2 is a diagram showing a configuration of an internal to the vehicle according to the exemplary embodiment of the present invention;

FIG. 3 is a control diagram of the vehicle according to the exemplary embodiment of the present invention;

FIG. 4 is a perspective view of a shift command input portion according to the exemplary embodiment of the present invention;

FIG. 5A and FIG. 5B are diagrams for describing a method of seating a vehicle accessory on a shift command input portion according to the exemplary embodiment of the present invention;

FIG. 6A, FIG. 6B, FIG. 6C, and FIG. 6D are diagrams for describing a relationship between a change in position of a vehicle accessory and a shift command according to various embodiments of the present invention;

FIG. 7 is a diagram for describing a relationship between the rotation of a vehicle accessory and a shift command according to the exemplary embodiment of the present invention; and

FIG. 8 is a flowchart for describing a control method for the vehicle according to the exemplary embodiment of the present invention.

It may be understood that the appended drawings are not necessarily to scale, presenting a somewhat simplified representation of various features illustrative of the basic principles of the invention. The specific design features of the present invention as included herein, including, for example, specific dimensions, orientations, locations, and shapes will be determined in part by the particularly intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

A vehicle and a control method for the same will be described more specifically below with reference to the accompanying drawings.

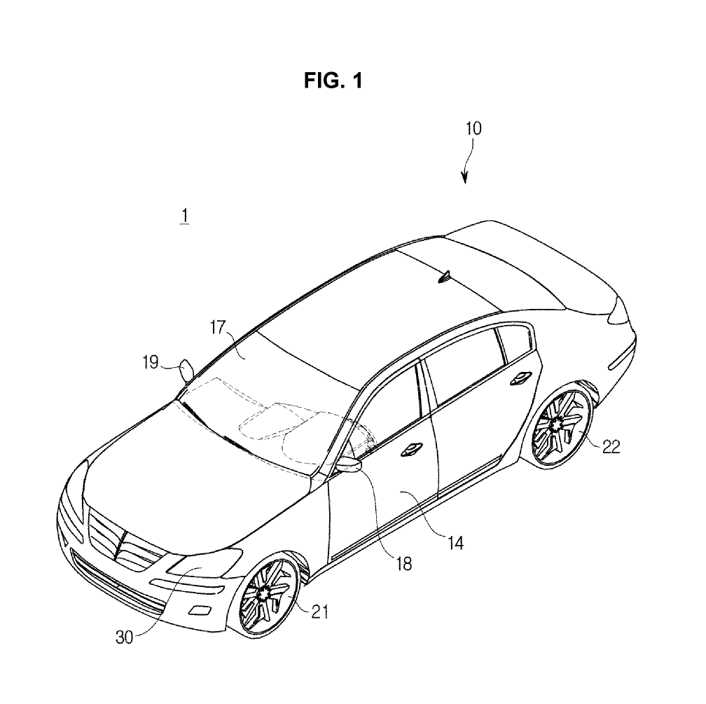

FIG. 1 is a diagram showing an external form of a vehicle according to an exemplary embodiment of the present invention.

As shown in FIG. 1, an exemplary embodiment of the vehicle includes a main body 10 configured to form an external form of a vehicle 1, wheels 21 and 22 configured to move the vehicle 1, doors 14 configured to shield the internal to the vehicle 1 from the outside, a front glass 17 configured to provide a driver within the vehicle 1 with a front field of view of the vehicle 1, and side mirrors 18 and 19 configured to provide the driver with rear fields of view of the vehicle 1.

The wheels 21 and 22 include front wheels 21 located in the front of the vehicle and rear wheels 22 located in the rear of the vehicle, and the front wheels 21 or the rear wheels 22 may receive a rotational force from a driving portion and move the main body 10 forwards and backwards thereof.

The doors 14 are rotatably provided on the right and left sides of the main body 10, the driver can board the vehicle 1 at a time of opening, and the internal to the vehicle 1 is shielded from the outside thereof at a time of being closed.

The front glass 17 may be provided on an upper front side of the main body 10 so that the driver within the vehicle 1 can obtain information on a field of view in front of the vehicle 1 and is also referred to as a windshield glass.

Also, the side mirrors 18 and 19 include a left side mirror 18 provided on the left side of the main body 10 and a right side mirror 19 provided on the right side of the main body 10 and enable the driver within the vehicle 1 to obtain information on fields of view of a side of and a side behind the vehicle 1.

Furthermore, lamps 30 used to secure visibility or inform people outside the vehicle of a traveling route may be provided in a front surface and/or rear surface of the vehicle.

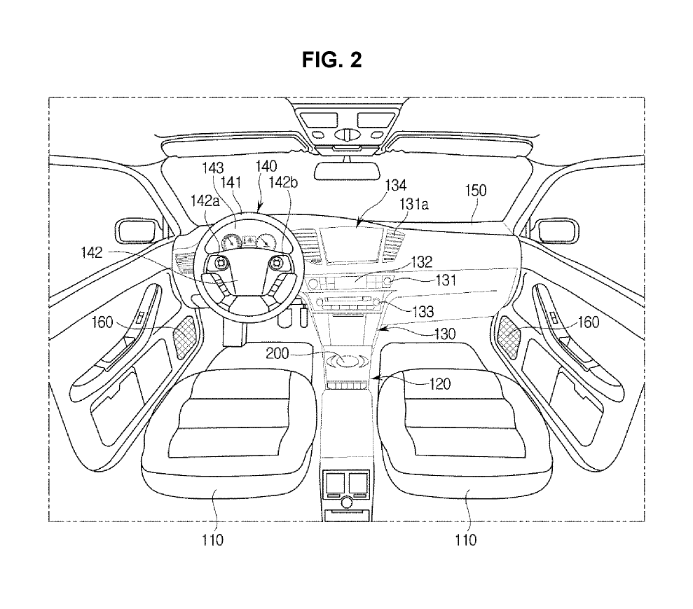

FIG. 2 is a diagram showing a configuration of the internal to the vehicle according to the exemplary embodiment of the present invention.

As shown in FIG. 2, the vehicle 1 may include seats 110 on which the driver and the like sit and a dashboard 150 including a gear box 120, a center fascia 130, a steering wheel 140, and the like.

The steering wheel 140 provided in the dashboard 150 is a device configured to control a traveling direction of the vehicle 1 and may include a rim 141 gripped by the driver and a spoke 142 connected to a steering device of the vehicle 1 and configured to connect the rim 141 and a hub of a rotation shaft for steering. In accordance with an exemplary embodiment of the present invention, operation devices 142a and 142b configured to control various devices in the vehicle 1, for example, an audio device and the like, may be provided in the spoke 142.

A cluster 143 may display a speed gauge indicating a speed of the vehicle and an revolution per minute (RPM) gauge indicating an RPM of the vehicle. The driver can verify information on the vehicle at a glance. Furthermore, the cluster 143 may display information on the vehicle 1, information on the traveling of the vehicle 1. For example, the cluster 143 may display a distance in which the vehicle can travel based on an amount of remaining fuel, navigation information, audio information, and the like.

Although not shown in the drawing, a head up display (HUD) configured to display visual information provided to the driver in the front glass 17 may be provided in the dashboard 150.

An air conditioner 131, a clock 132, an audio device 133, a display 134, and the like may be disposed in the center fascia 130 provided in the dashboard 150.

The air conditioner 131 keeps the internal to the vehicle 1 comfortable by adjusting a temperature, humidity, air cleanliness, and an air flow in the vehicle 1. The air conditioner 131 may include at least one discharge port 131a disposed in the center fascia 130 and configured to discharge air. Buttons, dials, or the like configured to control the air conditioner 131 or the like may be disposed in the center fascia 130. An occupant including the driver may control the air conditioner 131 using the buttons disposed in the center fascia 130.

The clock 132 may be provided around the buttons or the dials configured to control the air conditioner 131.

The audio device 133 may include an operation panel having a plurality of buttons configured to perform functions of the audio device 133. The audio device 133 may provide a radio mode used to provide radio functions and a media mode used to reproduce audio files in various storage media including audio files.

The audio device 133 may output an audio file through speakers 160 as a sound. Although a case in which the speakers 160 are provided inside the doors is exemplified in FIG. 2, a position where the speaker 160 is provided is not limited thereto.

The display 134 may display various information directly or indirectly associated with the vehicle. For example, the display 134 may display direct information including navigation information related to the vehicle and state information related to the vehicle and indirect information including multimedia information including photographs and moving images provided from the inside and outside of the vehicle.

To the present end, the display 134 may realized by a liquid crystal display (LCD), a light emitting diode (LED), a plasma display panel (PDP), an organic light emitting diode (OLED), a cathode ray tube (CRT), or the like, but the present invention is not limited thereto.

A shift command input portion 200 configured to change a speed of the vehicle 1 may be provided in the gear box 120.

A method of receiving an input of a shift command by the shift command input portion 200 will be described more specifically below.

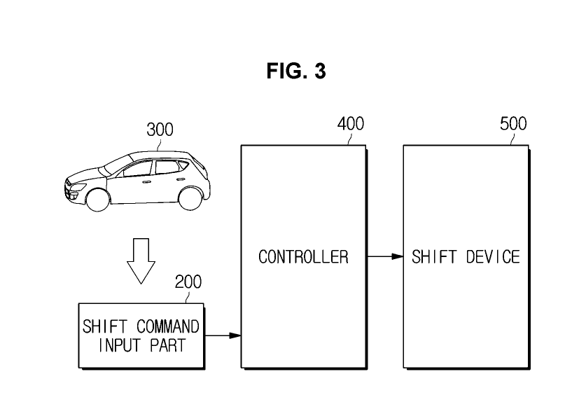

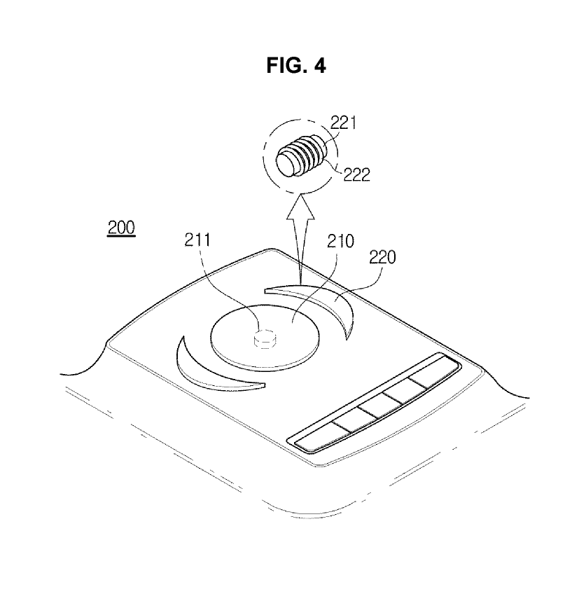

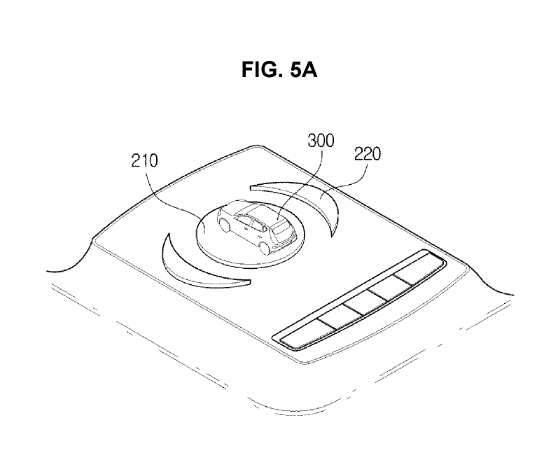

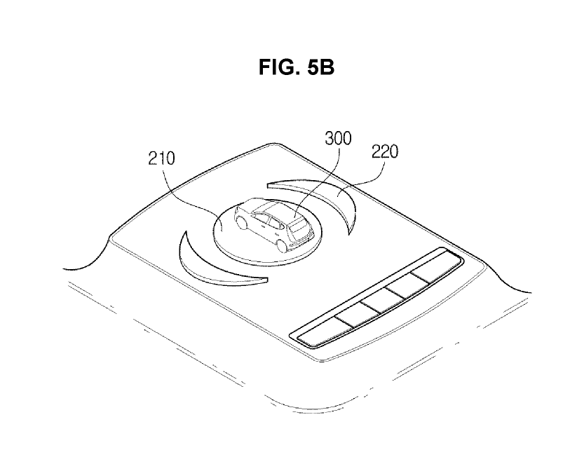

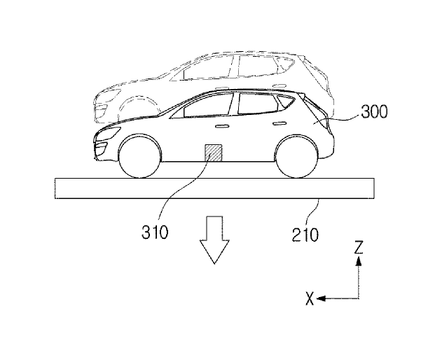

FIG. 3 is a control diagram of the vehicle according to the exemplary embodiment of the present invention, FIG. 4 is a perspective view of a shift command input portion according to the exemplary embodiment of the present invention, and FIG. 5A and FIG. 5B are diagrams for describing a method of seating a vehicle accessory on a shift command input portion according to the exemplary embodiment of the present invention.

Referring to FIG. 3, the vehicle 1 according to the embodiment may include a vehicle accessory 300, the shift command input portion 200 configured to receive an input of a shift command, a shift device 500 configured to change a shift range, and a controller 400 configured to control each configuration of the vehicle 1.

The shift device 500 may change a shift range of the vehicle 1. To be specific, when a shift command is input to the shift command input portion 200 which will be described below, the shift device 500 may perform the shifting to a shift range corresponding to the input shift command.

The vehicle accessory 300 (an accessory) may mean all kinds of accessories provided separately from the main vehicle body 1. For example, the vehicle accessory 300 according to the embodiment may be a smart key configured for controlling the vehicle 1 at a long distance. When the vehicle accessory 300 is realized as a smart key, the vehicle accessory 300 may receive a door lock command of the vehicle 1, a door unlock command of the vehicle 1, a startup command of the vehicle 1, a shutoff command of the vehicle 1, or the like from the outside thereof and transmit the commands to the vehicle 1.

Also, the vehicle accessory 300 may include a metal portion 310 formed of a metal material therein. The metal portion 310 may receive attraction from the shift command input portion 200 which will be described below and enable the vehicle accessory 300 to be stably seated in the shift command input portion 200. This will be described below.

The vehicle accessory 300 may be realized in a form of the vehicle 1. In other words, the front, rear, side, and the like of the vehicle accessory 300 can be distinguished like in the actual vehicle 1.

The shift command input portion 200 may be provided so that the vehicle accessory 300 can be seated, and can receive an input of a startup command by seating the vehicle accessory 300. To the present end, the shift command input portion 200 may include a seating portion 210 in which the vehicle accessory 300 is seated.

One surface of the seating portion 210 may be exposed on the gear box 120 so that the vehicle accessory 300 can be stably seated. Referring to FIG. 4, one circular surface of the seating portion 210 according to the embodiment may be exposed to the outside. Here, since there is no restriction on a shape to be realized, the seating portion 210 can be variously realized within the technical idea in which the vehicle accessory 300 can be stably seated.

An electromagnet 211 may be provided in a lower portion of one surface of the seating portion 210 exposed to the outside. The electromagnet 211 of the seating portion 210 provides attraction in relation to the metal portion 310 within the vehicle accessory 300, and thus the vehicle accessory 300 can be guided to be seated on the one surface of the seating portion 210. Referring to FIG. 4, the electromagnet 211 according to the embodiment may be provided in a lower center of the one circular surface of the circular seating portion 210. Here, since there is no restriction on a position to be provided, the electromagnet 211 may be variously provided within the technical idea in which the vehicle accessory 300 to be seated in one surface of the seating portion 210 is guided.

Referring to FIG. 5A, the driver who wants to start the vehicle 1 can input a startup command by seating the vehicle accessory 300 possessed by the driver in the shift command input portion 200. When the driver moves the vehicle accessory 300 in a direction of an arrow so that the vehicle accessory 300 approaches the seating portion 210 of the shift command input portion 200, a magnitude of attraction provided to the metal portion 310 within the vehicle accessory 300 by the electromagnet 211 inside the seating portion 210 may increase.

As a result, the driver can stably seat the vehicle accessory 300 in the one surface of the seating portion 210. Referring to FIG. 5B, since the electromagnet 211 is provided in a lower center of the one surface of the seating portion 210, the vehicle accessory 300 can be stably seated in an upper center of the one surface of the seating portion 210. Thus, the vehicle 1 can receive an input of a startup command.

When the vehicle 1 is started in a response to the startup command, the shift command input portion 200 may receive an input of a shift command corresponding to a change in position of the seated vehicle accessory 300. To the present end, the shift command input portion 200 may further include a detector 220 configured to detect a change in position of the seated vehicle accessory 300.

The detector 220 may be provided near the seating portion 210 to be able to detect a change in position of the vehicle accessory 300. Referring to FIG. 4, the detector 220 according to the exemplary embodiment of the present invention may be provided adjacent to a portion of the external periphery of the circular seating portion 210. Here, since there is no restriction on a position to be provided, the detector 220 may be variously provided within the technical idea in which a change in position of the vehicle accessory 300 is detected.

The detector 220 may form a magnetic field around the seating portion 210 and detect a change in position of the vehicle accessory 300 in accordance with a change in the formed magnetic field. To the present end, the detector 220 may include a permanent magnet 221 configured to form a magnetic field around the seating portion 210 and a coil 222 through which an induced current corresponding to the change in the formed magnetic field flows.

A plurality of permanent magnets 221 may be provided to surround the seating portion 210 at the external periphery of the seating portion 210, and a plurality of coils 222 may be provided to surround each of the plurality of permanent magnets 221 from the outside. Since the plurality of permanent magnets 221 is disposed along the seating portion 210 at the external periphery of the seating portion 210, a magnetic field may be formed in a region including the seating portion 210.

In the instant case, since the metal portion 310 of the vehicle accessory 300 receiving attraction from the electromagnet 211 also has magnetism, a change in position of the vehicle accessory 300 may cause a change in the magnetic field. When the magnetic field varies, an induced current flows through the coil 222 surrounding the permanent magnet 221 corresponding to the varied magnetic field. Thus, a change in position of the vehicle accessory 300 may be confirmed by detecting such an induced current.

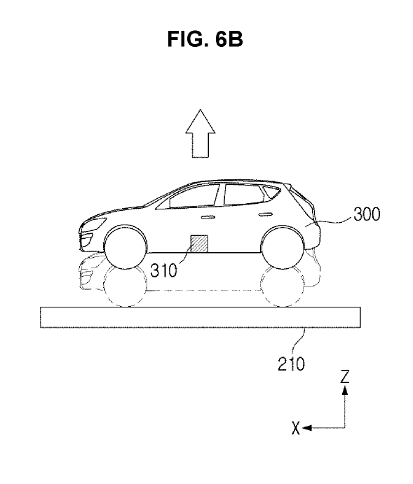

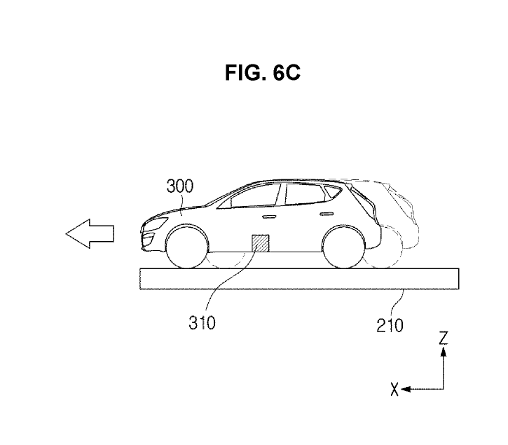

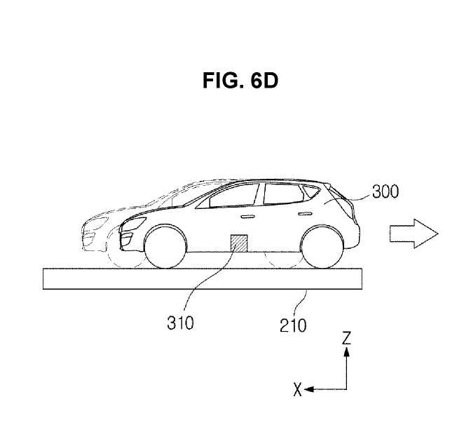

When the change in position of the vehicle accessory 300 is confirmed, the shift command input portion 200 may receive an input of a shift command corresponding to the confirmed change in position. Furthermore, the controller 400 may control the shift device 500 in accordance with the input shift command. A method of receiving an input of a shift command in accordance with a change in position of the vehicle accessory 300 and controlling the shift device 500 will be described more specifically below with reference to FIG. 6A, FIG. 6B, FIG. 6C, and FIG. 6D.

FIG. 6A, FIG. 6B, FIG. 6C, and FIG. 6D are diagrams for describing a relationship between a change in position of a vehicle accessory and a shift command according to various embodiments of the present invention. In FIG. 6A, FIG. 6B, FIG. 6C, and FIG. 6D, an x axis may represent the front of the vehicle 1 and a z axis may represent a direction perpendicular to the ground.

The shift command input portion 200 may receive an input of a shift command corresponding to a change in position including forward movement, backward movement, upward movement, and downward movement of the vehicle accessory 300 seated on the seating portion 210.

For example, the shift command input portion 200 may receive an input of a shift command to a parking (P) stage by detecting the downward movement of the seated vehicle accessory 300. Referring to FIG. 6A, when the driver moves the vehicle accessory 300 in a direction of an arrow, the shift command input portion 200 may receive an input of a shift command to the P stage by detecting such movement.

After the shift command input portion 200 receives the input of the shift command to the P stage, the controller 400 may control the shift device 500 to change the shift range to the P stage.

An another example, the shift command input portion 200 may receive an input of a shift command to a neutral (N) stage by detecting the upward movement of the seated vehicle accessory 300. Referring to FIG. 6B, when the driver moves the vehicle accessory 300 in a direction of an arrow, the shift command input portion 200 may receive an input of a shift command to the N stage by detecting such movement.

After the shift command input portion 200 receives the input of the shift command to the N stage, the controller 400 may control the shift device 500 to change the shift range to the N stage.

As yet another example, the shift command input portion 200 may receive an input of a shift command to a driving (D) stage by detecting the forward movement of the seated vehicle accessory 300. Referring to FIG. 6C, when the driver moves the vehicle accessory 300 in a direction of an arrow, the shift command input portion 200 may receive an input of a shift command to the D stage by detecting such movement.

After the shift command input portion 200 receives the input of the shift command to the D stage, the controller 400 may control the shift device 500 to change the shift range to the D stage.

As yet another example, the shift command input portion 200 may receive an input of a shift command to a reverse (R) stage by detecting the backward movement of the seated vehicle accessory 300. Referring to FIG. 6D, when the driver moves the vehicle accessory 300 in a direction of an arrow, the shift command input portion 200 may receive an input of a shift command to the R stage by detecting such movement.

After the shift command input portion 200 receives the input of the shift command to the R stage, the controller 400 may control the shift device 500 to change the shift range to the R stage.

In addition to the embodiment of FIG. 6A, FIG. 6B, FIG. 6C, and FIG. 6D, the shift command input portion 200 may receive an input of a shift command by detecting various changes in position of the vehicle accessory 300. For example, the shift command input portion 200 detects the forward movement of the seated vehicle accessory 300 and may receive an input of a manual shift (a+stage/a−stage) of the D stage in accordance with a forward movement distance.

Also, the shift command input portion 200 may receive an input of a shift command by detecting rotation of the vehicle accessory 300.

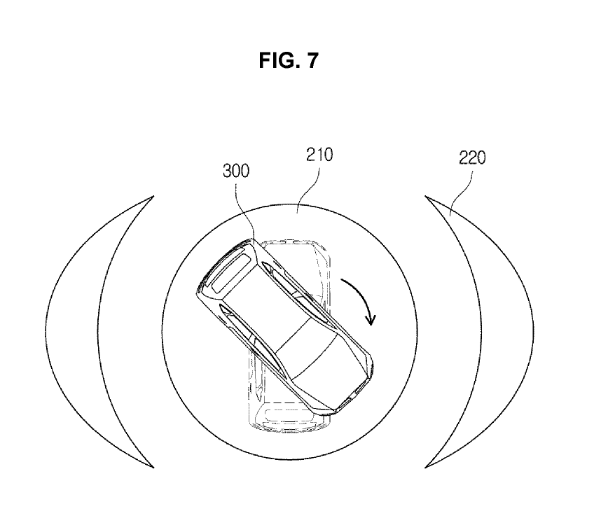

FIG. 7 is a diagram for describing a relationship between the rotation of a vehicle accessory and a shift command according to the exemplary embodiment of the present invention.

Unlike FIG. 6C, the shift command input portion 200 may receive an input of a shift command to the R stage by detecting the rotation of 180° of the seated vehicle accessory 300. Referring to FIG. 7, when the driver rotates the vehicle accessory 300 in a direction of an arrow, the shift command input portion 200 may receive an input of a shift command to the R stage by detecting such rotation.

After the shift command input portion 200 receives the input of the shift command to the R stage, the controller 400 may control the shift device 500 to change the shift range to the R stage.

Further, when the vehicle accessory 300 is separated from the seating portion 210 of the shift command input portion 200, the shift command input portion 200 may receive an input of a shutoff command by detecting such separation. In the instant case, to avoid inconsistency with the case of FIG. 6B, the shift command input portion 200 may receive an input of a shutoff command when a time at which the vehicle accessory 300 is separated from the seating portion 210 exceeds a predetermined reference time. Here, the reference time may refer to a maximum time taken to separate the vehicle accessory 300 from the seating portion 210 to input a shift command and may be determined using an input from the outside thereof or an internal determination of the vehicle 1.

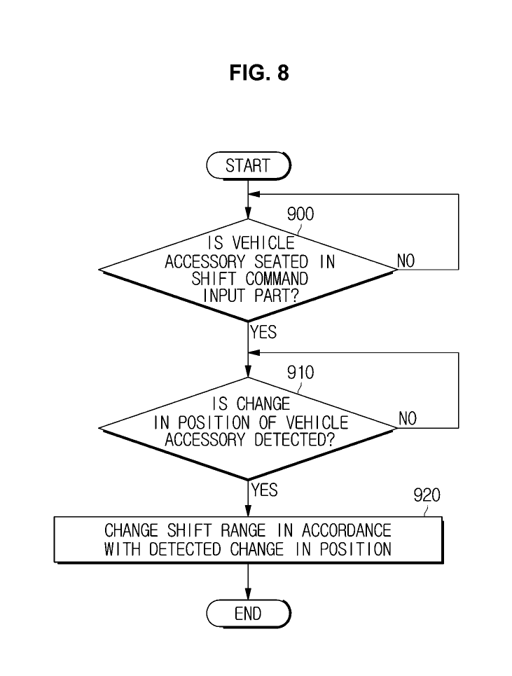

FIG. 8 is a flowchart for describing a control method for the vehicle according to the exemplary embodiment of the present invention.

First, the vehicle 1 may confirm whether the vehicle accessory 300 is seated in the shift command input portion 200. To be specific, the vehicle 1 may confirm whether the vehicle accessory 300 is seated on the seating portion 210 of the shift command input portion 200. When it is determined that the vehicle accessory 300 is not seated on the seating portion 210 of the shift command input portion 200, the vehicle 1 may repeatedly confirm whether the vehicle accessory 300 is seated.

On the other hand, when it is determined that the vehicle accessory 300 is seated on the seating portion 210 of the shift command input portion 200, the vehicle 1 may detect a change in position of the vehicle accessory 300. To be specific, the vehicle 1 may confirm whether a change in position of the vehicle accessory 300 is detected by the detector 220 of the shift command input portion 200. When it is determined that a change in position of the vehicle accessory 300 is not detected by the detector 220 of the shift command input portion 200, the vehicle 1 may repeatedly confirm whether there is a change in position of the vehicle accessory 300.

In contrast, when a change in position of the vehicle accessory 300 is detected by the detector 220 of the shift command input portion 200, the vehicle 1 may change the shift range in accordance with the detected change in position.

As described above, the vehicle 1 according to the exemplary embodiment of the present invention can receive an input of a shift command due to a change in position of the vehicle accessory 300 to provide an environment in which the driver can intuitively input a shift command.

Also, since the vehicle 1 according to the exemplary embodiment of the present invention receives an input of a shift command by the vehicle accessory 300 which is portable by the driver, the security of the vehicle 1 can be enhanced.

In accordance with an aspect of the present invention, a driver can intuitively input a shift command by changing a position of a vehicle accessory.

In accordance with another aspect of the present invention, since a shift command can be input using a vehicle accessory possessed by a driver, security of a vehicle can be enhanced.

For convenience in explanation and accurate definition in the appended claims, the terms “upper”, “lower”, “internal”, “outer”, “up”, “down”, “upper”, “lower”, “upwards”, “downwards”, “front”, “rear”, “back”, “inside”, “outside”, “inwardly”, “outwardly”, “internal”, “external”, “internal”, “outer”, “forwards”, and “backwards” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described to explain certain principles of the invention and their practical application, to enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A vehicle comprising:
a vehicle accessory;
a shift command input portion in which the vehicle accessory is configured to be seated and which receives an input of a shift command corresponding to a change in position of the seated vehicle accessory;
a shift device configured to change a shift range; and
a controller configured to control the shift device to change the shift range in accordance with the shift command input by the shift command input portion.

2. The vehicle according to claim 1, wherein the shift command input portion receives the input of the shift command corresponding to the change in position including at least one of forward movement, backward movement, rotation, upward movement, and downward movement of the seated vehicle accessory.

3. The vehicle according to claim 1, wherein
the shift command input portion includes a seating portion in which the vehicle accessory is seated; and
a detector configured to detect a change in position of the vehicle accessory seated in the seating portion.

4. The vehicle according to claim 3, wherein the vehicle accessory includes a metal portion provided therein.

5. The vehicle according to claim 4, wherein the seating portion includes an electromagnet configured to provide attraction to the metal portion of the vehicle accessory.

6. The vehicle according to claim 3, wherein the detector forms a magnetic field around the seating portion and detects the change in position of the vehicle accessory in accordance with a change in the formed magnetic field.

7. The vehicle according to claim 6, wherein
the detector includes a permanent magnet configured to form the magnetic field around the seating portion; and
a coil through which an induced current corresponding to a change in the formed magnetic field flows.

8. The vehicle according to claim 1, wherein the shift command input portion receives an input of a startup command when the vehicle accessory is seated.

9. The vehicle according to claim 8, wherein the shift command input portion receives an input of a shutoff command when the seated vehicle accessory is separated.

10. The vehicle according to claim 1, wherein the vehicle accessory is provided in a form of a vehicle.

11. The vehicle according to claim 1, wherein the vehicle accessory receives an input of at least one of a door lock command and a door unlock command of the vehicle.

12. A control method for a vehicle including a shift command input portion in which a vehicle accessory is configured to be seated, the control method including:
receiving an input of a shift command corresponding to a change in position of the seated vehicle accessory; and
changing a shift range in accordance with the input shift command.

13. The control method according to claim 12, wherein the receiving of the input of the shift command includes receiving an input of a shift command corresponding to the change in position including at least one of forward movement, backward movement, rotation, upward movement, and downward movement of the seat vehicle accessory.

14. The control method according to claim 12, wherein
the receiving of the input of the shift command includes forming a magnetic field around a seating portion in which the vehicle accessory is seated; and
receiving an input of the shift command according to a change in the magnetic field generated due to a change in position of the vehicle accessory.

15. The control method according to claim 14, wherein the forming of the magnetic field includes forming the magnetic field using a permanent magnet provided adjacent to the seating portion.

16. The control method according to claim 14, wherein the receiving of the input of the shift command in accordance with the change in the magnetic field includes receiving an input of the shift command on a basis of an induced current corresponding to the change in the magnetic field.

17. The control method according to claim 12, further including starting the vehicle when the vehicle accessory is seated in the shift command input portion.

18. The control method according to claim 17, wherein the starting of the vehicle includes starting the vehicle when the vehicle accessory is seated in the shift command input portion due to attraction provided by an electromagnet of the shift command input portion.

19. The control method according to claim 12, further including shutting off the vehicle when the seated vehicle accessory is separated from the shift command input portion.

20. The control method according to claim 12, wherein the receiving of the input of the shift command includes receiving an input of a shift command corresponding to a change in position of the seated vehicle accessory provided in a vehicle shape.

21. The control method according to claim 12, further including receiving an input of at least one of a door lock command and a door unlock command of the vehicle by the vehicle accessory.
